(19) United States
(12) Patent Application Publication
(10) Pub. No.: US 2015/0236703 A1
(43) Pub. Date: Aug. 20, 2015

(54) METHOD FOR LOAD SHARE BALANCING IN A SYSTEM OF PARALLEL-CONNECTED GENERATORS USING SELECTIVE LOAD REDUCTION

(71) Applicant: Remy Technologies, LLC, Pendleton, IN (US)

(72) Inventor: Timothy J. Alfermann, Carmel, IN (US)

(21) Appl. No.: 14/626,633

(22) Filed: Feb. 19, 2015

Related U.S. Application Data
(60) Provisional application No. 61/941,691, filed on Feb. 19, 2014.

(51) Int. Cl. H03L 5/02; G05B 15/02

(52) U.S. Cl. CPC H03L 5/02; G05B 15/02

(57) ABSTRACT

A parallel generator system having at least one controller using selective load reduction for load share balancing, and a method for using selective load reduction for load share balancing in a parallel generator system.

### PRIORITY CLAIM AND CROSS-REFERENCE TO RELATED APPLICATIONS

This application claims the benefit under Title 35, U.S.C. §119(e) of U.S. Provisional Patent Application Ser. No. 61/941,691 filed Feb. 19, 2014 entitled METHOD FOR LOAD SHARE BALANCING IN A SYSTEM OF PARALLEL-CONNECTED GENERATORS USING SELECTIVE LOAD REDUCTION; and is related to U.S. patent application Ser. No. ______ entitled METHOD FOR LOAD SHARE BALANCING IN A SYSTEM OF PARALLEL-CONNECTED GENERATORS USING ACCUMULATED DAMAGE MODEL filed on Feb. 19, 2015 (Attorney Docket No. 22888-0206), and U.S. patent application Ser. No. ______ entitled METHOD FOR OPTIMIZING THE EFFICIENCY OF A SYSTEM OF PARALLEL-CONNECTED GENERATORS filed on Feb. 19, 2015 (Attorney Docket No. 22888-0210), the entire disclosures of which are incorporated herein by reference.

### BACKGROUND

The present disclosure generally relates to systems and methods for generating and distributing electrical power, and more particularly such systems and methods which involve multiple electrical generators connected in parallel.

Typically, a generator is a rotary electric machine of well-known type having a stator surrounded by a rotor that is driven through a belt or shaft by a prime mover (e.g., an engine) to electromagnetically induce electrical current in conductive windings of the stator, whereby mechanical power is converted into electrical power. A generator may be a DC type that produces direct current or an AC type that produces an alternating current, the latter type also referred to as an alternator. Where used to charge a battery that powers an electrical system, alternator output is rectified. A parallel system of DC generators may include an invertor to convert DC generator output to AC system output power as necessary. Reference herein to a “generator” may refer to either type (i.e., DC or AC), unless an alternator is specified.

Parallel generator systems, wherein multiple generators one type (i.e., DC or AC) are electrically connected to each other in parallel, may be adapted for use in stationary installations, usually to provide backup power for a building or campus, or in mobile installations, and may be a primary power source for charging batteries that provide electrical power for various types of vehicles, such as over-the-road tractors or large buses, for example.

Some parallel generator systems employ a plurality of prime movers to drive the multiplicity of generators. For example, an engine may be dedicated to driving only a respective one of the multiplicity of parallel-connected generators, as is typical in large stationary backup power systems.

Other parallel generator systems, particularly those used in vehicles, employ a single engine to drive the multiplicity of generators. For example, the single engine of an over-the-road tractor or large bus drives each of the multiplicity of parallel-connected generators, which are typically alternators mounted to the engine and driven by the crankshaft through a common belt. Such vehicle-based systems of parallel-connected alternators typically provide rectified DC power to a battery (or multiple batteries) that provide power to the vehicle's electrical system. The multiple alternators may be identical to each other, and may be driven at a common speed that is a ratio of the engine crankshaft speed. The output of the stator windings of each alternator providing power to the generator system (i.e., each active generator) is normally controlled by a single voltage regulator common to all alternators in the system, or a single, dedicated voltage regulator for that respective alternator. The strength of each rotor's moving magnetic field, which induces current flow in the stator windings of the surrounding stator to generate alternator output voltage, is controlled by the voltage regulator(s).

Parallel generator systems are well-known for ensuring an uninterrupted supply of power and have significant advantages over single large generator units in areas of cost effectiveness, flexibility, expandability, ease of maintenance and serviceability, and reliability.

The individual generator units operating in parallel systems are typically of smaller capacities, and may be identical or of variable output. In either case, these units can be connected in parallel with paralleling switchgear to achieve maximum output during peak requirement or the desired minimal output during other times. Often, each generator has its own digital microcontroller (referred to herein as a generator controller) which may be a plug and play device. Each of the generator controllers controls the operation of its respective individual generator unit, and cooperates in the operation of the overall parallel system, which may be controlled by an optionally included master controller. The generators may coordinate among themselves or, optionally, may designate a system master controller that is either internal to one generator or an external electronic control unit.

Using multiple generator units in parallel offers greater flexibility than using a single large-sized generator of a high capacity. Multiple smaller generators operating in parallel do not need to be grouped together and can be distributed such that they are remotely located from each other and do not require a single, large space, as would be needed in the case of a single, larger generator. Furthermore, it is often difficult when sizing generators to match load requirements to accurately project increases in load and adequately plan for anticipated additional loads; by operating generators in parallel, variations in load can be relatively easy to accommodate by adding additional parallel-connected generators for additional power supply provided. Thus, by operating generators in a parallel system, it is easier to allow for an increase in the load requirement. Moreover, if a generator unit in the parallel system breaks down or requires maintenance, that individual unit can be removed from service, and repaired or replaced, without disrupting the functioning of the other generator units in the system.

As those of ordinary skill in the art appreciate, to avoid damage the introduction (or reintroduction) of an incoming alternator to active service within a parallel generator system requires its synchronization, as closely as possible, with the other, operating alternators of the system, before they are interconnected through a common bus. Synchronization of an incoming alternator may be accomplished by connecting one operating alternator of the system to the bus (referred to as the bus alternator), and then synchronizing the incoming alternator to the bus alternator before closing the incoming alternator's main power contactor. Typically, the alternators are synchronized when: they have equal terminal voltages (setpoints), which may be achieved through adjustment of the incoming alternator's field strength; they are of equal frequency, which may be achieved through adjustment of the incoming alternator's rotational speed (though usually not called for in vehicle-based system where identical alternators are driven by the engine crankshaft through a common belt); and their phase voltages are in proper relation. Automatic synchronizing equipment is also known to those of ordinary skill in the art and can be utilized in many situations for bringing an alternator into active service in a parallel system. The above synchronization functions are typically regulated by the generator controllers and/or the optional master controller. The synchronization of DC type generators is relatively simpler, as it may be limited to equalizing their voltage setpoints.

The redundancy inherent in parallel operation of multiple generators provides greater reliability than is offered by single generator unit for critical loads. If one unit fails, the critical loads are redistributed among other units in the system, typically on a priority basis. In many applications, critical loads needing the highest degree of reliable power account for only a fraction of the overall power generated by the system, and parallel systems provide the redundancy necessary to maintain power to critical loads even if one of its generator units fails. The redundancy inherent in a parallel system thus provides multiple layers of protection and ensures an uninterrupted supply of power for critical circuits.

In a parallel generator system, the entire load is shared by all of the parallel-connected generators operating in the system, the active generators. In prior systems, load sharing between the active, or operating, generators of the system is typically done to ensure all of these active generators contribute the same power toward the system load, or so that they all share the same voltage setpoint. This approach, however, ignores the fact that some generator units may be deactivated for significant periods over the life of the system, and can result in these deactivation periods not being equally allocated among the multiplicity of generators.

Further, although each of the multiplicity of parallel-connected generators may be co-located and operate under similar environmental conditions, oftentimes various ones of the multiplicity of parallel-connected generators, whether part of the original system design or subsequently added, are located remotely from the others and operate under significantly different conditions. For example, one of the generators of a parallel system may operate under relatively harsher conditions than one or more of the others and consequently suffer relatively greater accumulated damage, whereby it is relatively more prone to fail during system operation. Continuing reliance as usual on the operation of a generator unit which has relatively greater likelihood of failure can result in its needing replacement or repair unpredictably and inconveniently. Moreover, the unpredicted failure of such a generator unit while a parallel generator system is under a high system load conditions when, albeit temporarily, all generators in the system may be operating, can undermine system reliability.

More efficient utilization of parallel-connected generators, and thus improved reliability and efficiency of a parallel generator system would be facilitated by systems and methods that better distribute the electrical load shared among the active generators in a manner that better equalizes their operating temperatures, and stress distribution, over time, thereby maximizing system service life.

### SUMMARY

The present disclosure provides a parallel generator system having a controller using selective load reduction for load share balancing, and a method for using selective load reduction for load share balancing in a parallel generator system. In accordance with the teachings of the present disclosure, more efficient utilization of the generator units of a parallel generator system is facilitated, thereby improving system reliability and efficiency vis-à-vis prior parallel generator systems, and maximizing the service life of the system.

The present disclosure provides a parallel generator system having a service life and including a system bus adapted for connection to an electrical load, a plurality of generator units electrically connectable in parallel to the system bus, and a plurality of controllers. Each generator unit is active when providing electrical power to the system bus, and various ones of the generator units being selectively active or inactive during the system service life. A portion of the electrical load of an active generator unit is incrementally transferred to another active generator unit by a controller on the basis of an indication that the loads of the active generator units are disallowably unbalanced, whereby load share balancing among the plurality of generator units occurs over the system service life.

The present disclosure also provides a method for using selective load reduction for load share balancing in a parallel generator system, including: selectively activating or deactivating one or more of a plurality of generator units during a portion of the system service life; determining an indication that the loads of the active generator units are disallowably unbalanced; and using at least one controller to incrementally transfer a portion of the electrical load of an active generator unit to another active generator unit on the basis of the determined indication, whereby load share balancing among the plurality of generator units occurs over the system service life.

Certain measurable aspects of each generator unit in a parallel system reflect its being operated under conditions understood to adversely affect its continued reliability. The probability of generator failure during operation increases with its time in operation, particularly under one or more stressing conditions understood to correlate with a shortening of its service life. Such conditions typically include, for example, operation under high temperature. In other words, for a given operating period, the failure of a generator unit operating at relatively higher temperatures is likely to occur before the failure of that unit operating at lower temperatures. Generator temperature can be affected, for example, by its design, capacity, component materials, location, installation placement, cooling provisions, and electrical loading, and other factors. If, over the accumulated time in operation, a generator unit's temperature is significantly higher rather than lower, it is generally understood by those of ordinary skill in the art, that the likelihood of earlier failure will be greater. This may be due to greater wear and material degradation experienced with operation at higher temperatures influenced by one or more of the above-mentioned factors.

Reducing the electrical load share carried by an individual active generator unit exhibiting a significantly higher operating temperature, relative to the other active generator units to which it is parallel-connected, can reduce the stress on that generator unit, and help prolong its service life without its burden being unduly shifted to the other active generators that consequently carry relatively greater portions of the total system load. The stress reduction on the partially load-relieved generator unit would be reflected by a reduction in its operating temperature, and thus its failure-inducing thermal stress.

In accordance with the present disclosure, if all parallel-connected generators in the system are in service, or are rotated into and out of service on a regular basis during system operation, the electrical load on a generator unit whose operating temperature is deemed excessive, is incrementally reduced, and shifted to the other active generator units, resulting in the operating temperatures of active generators being substantially maintained, over time, near the average operating temperature of all of the active generators.

In one embodiment of the present disclosure, all generator units of the parallel generator system are rotated on a regular basis into and out of active service, with the load of the active generator unit with an operating temperature significantly higher than the average operating temperature of all active generator units, is incrementally reduced and distributed to the other active generators. Accordingly, the service lives of the accumulated damages of all generators in the system may tend towards equalization, resulting in maximal system life with minimal interim, unpredicted, and inconvenient generator unit failures that undermine system reliability and efficiency.

Thus, a system and method according to the present disclosure better allows the service lives of all generators of a parallel system to be made substantially equivalent, despite at least one generator unit, when active, bearing a lesser portion of the total system load than the other active generator units.

In certain parallel generator system embodiments according to the present disclosure, the generator controller of each generator serially communicates with the system's optionally included master controller. Compared to parallel communication networks, serial communication networks generally afford reduced system costs and complexity, and can better accommodate longer data transmission distances and smaller controller packaging spaces, further contributing to system cost effectiveness and reliability. Moreover, serial communication networks are often required by customers of parallel generator systems, and sometimes can be more easily and less expensively incorporated into a preexisting communication infrastructure.

### BRIEF DESCRIPTION OF THE DRAWINGS

The above-mentioned aspects and other characteristics and advantages of a system and/or method according to the present disclosure will become more apparent and will be better understood by reference to the following description of exemplary embodiments taken in conjunction with the accompanying drawings, wherein:

FIG. 1 depicts a schematic of an example parallel generator system embodiment according to the present disclosure;

FIG. 2 shows an example of an active generator unit rotation scheduling algorithm for use in a method embodiment according to the present disclosure; and

FIG. 3 shows an example of a load share algorithm for use in a method embodiment according to the present disclosure.

### DETAILED DESCRIPTION OF EXEMPLARY EMBODIMENT(S)

The embodiments of the present invention described below are not intended to be exhaustive or to limit the invention to the precise forms disclosed in the following detailed description. Rather, the embodiments are chosen and described so that others skilled in the art may appreciate and understand the principles and practices of the present invention.

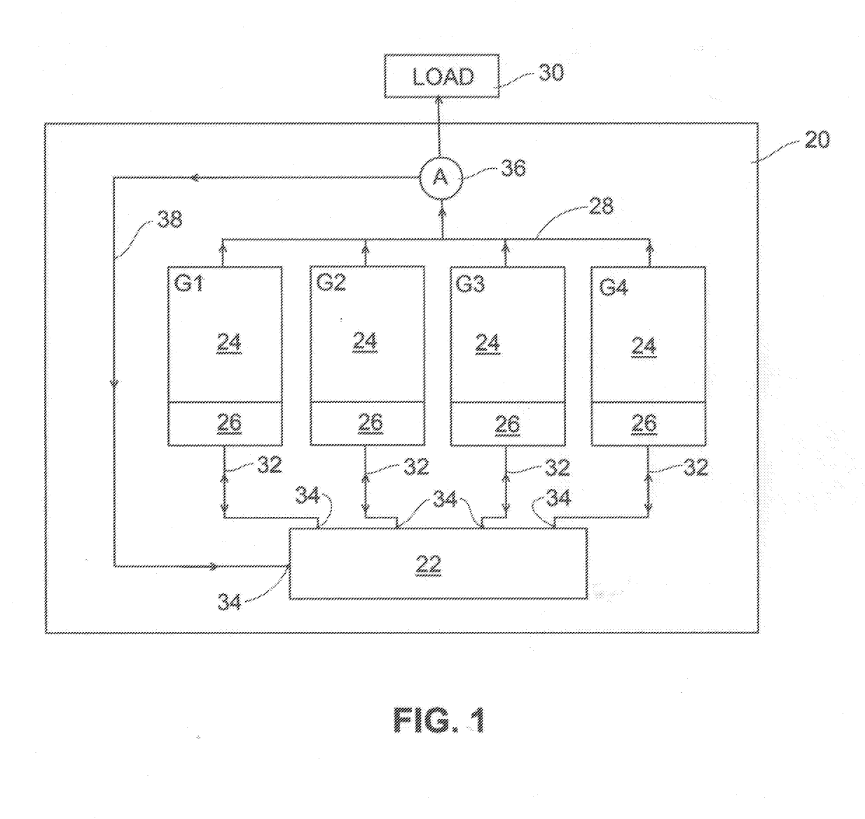

FIG. 1 schematically shows an example parallel generator system embodiment connected to an electrical load. Depicted system 20 includes master controller 22, and four parallel-connected generator units 24, respectively designated G1, G2, G3, and G4, each with its own generator controller 26. As discussed further below, the inclusion of master controller 22 is optional; the generator controller(s) 26 of one generator unit 24, or of the multiplicity of generator units 24, may be adapted to carry out the method of load share balancing disclosed herein. The generator units 24 may be commonly driven by a single prime mover, or each may be driven independently of the others by a separate prime mover. The generator units 24 may also be of either DC or AC type.

In the depicted embodiment, the optionally-included master controller 22 is separate and located remotely from each of generator units 24. Alternatively, in some embodiments the master controller 22 and the generator controller 26 of one of the generator units 24 (which may then be considered the master generator unit) can be integrated into a combined master/generator controller. As a further alternative, in some embodiments the intercommunicating generator controllers 26 of the multiplicity of generator units 24 included in system 20 can cooperatively perform the herein-disclosed method and decide between themselves which of the generator units 24 shall be affected (i.e., selectively activated or deactivated, or whose electrical load is partially transferred) according to the disclosed method. In such embodiments, the need for a separate master controller 22 and its attendant cost and packaging considerations may therefore be avoided.

The generator units 24 are each electrically connected to a system bus 28 when introduced into active service in the system 20. By becoming connected to the system bus 28, a driven generator unit 24 becomes active; active generator units 24 are parallel-connected to each other through the bus 28, and power generated by each generator unit 24 is transferred to the system load 30 through the bus 28.

In the depicted embodiment, regardless of whether active or inactive, each of the generator controllers 26 is individually in serial communication with the master controller 22 through a respective serial communication cable 32. From the perspective of a generator controller 26, and as is typical of serial communication concepts, each serial communication cable 32 has, in addition to its ground line, a transmit line over which data is communicated from the generator controller 26 to the system master controller 22, and a receive line over which data is communicated from the system master controller 22 to the generator controller 26. Each generator controller 26 is connected through its respective cable 32 to its respectively associated serial port 34 of the master controller 22. Alternatively, in some embodiments the communication cables 32 could be daisy-chained, such as those in which master controller 22 is omitted as discussed above.

An ammeter 36 may be provided between the system bus 28 and the system load 30, whereby the electric current provided by the system 20 to the load 30 is measured and provided, in the depicted embodiment, as an input to the master controller 22 for determining the magnitude of the load 30. Such an ammeter 36 may also be in serial communication with the master controller 22 via a serial communication cable 38. Alternatively, in some embodiments, the portion of load 30 borne by each active generator unit 24 can be measured by its generator controller 26, and these load portions summed up. For example, in some embodiments where the generator units are alternators, current can be determined from the duty cycle on all active alternator voltage regulators. Thus current, and thus the load 30, can be determined through measurement internal to the active generator unit(s) 24.

In one embodiment, upon a change in which ones of the system's generators units 24 are active, the active generators have a common, known voltage setpoint Vₛₑₜ. The load's total power demand on the system 20 may be determined by the master controller 22 using the current drawn by the load 30, as measured by and communicated from the ammeter 36. Alternatively, in another embodiment, upon a change in which ones of the system's generators units 24 are active, the active generators 24 have respectively different voltage setpoints. Regardless of whether the active generator units 24 have a single, common voltage setpoint, or various different voltage setpoints, the method described herein ensures substantially equal thermal load sharing between all generators 24 of the system 20 over time.

Based on the measured power demand on the system 20, its master controller 22 continually determines the number of generators 24 required to be active, N_{active}. The master controller 22 and the individual generator controllers 26 cooperate to selectively activate and deactivate the individual generator units 24, or shift portions of the total system load between active generator units 24, as discussed further below.

In accordance with the present disclosure, each active parallel-connected generator unit has its temperature compared to the average operating temperature of all active generators. If a particular generator unit has a higher temperature than permitted, the electrical load on that generator is reduced incrementally; the portion of the electrical load removed from the hotter-running generator is transferred to the other active generators. The load reduction can be achieved by reducing the voltage setpoint of the hotter-running generator in small incremental steps. Alternatively, in some embodiments the electrical loading can be redistributed between active generator units by increasing the setpoint(s) of the cooler-running generator(s), thereby reducing the thermal loading on the hotter-running generator unit. Some alternative embodiments may perform a combination of reducing and increasing voltage setpoints of the hotter and cooler-running generator units, respectively, to arrive at an electrical load redistribution that reduces the thermal loading on the hotter-running generator unit. This is an iterative process that continues, within specified limits, until all active generators share the same thermal load.

The activated generator unit list rotates based on time so that each unit has substantially equal time in active service. In some embodiments, the incremental load reduction for a particular generator may continue from one active generator rotation period to the next if that generator remains active. In other embodiments, load reduction for a particular generator may begin anew in the next active generator rotation period, if that generator remains active, with each active generator being reset at its respective initial voltage setpoint upon a change in which ones of the system's generators units 24 are active. In such embodiments, Vₛₑₜ for each active generator unit may be reset to its initial value at the start of a new active generator rotation period with a change in which ones of the system's generator units 24 are active, as mentioned above.

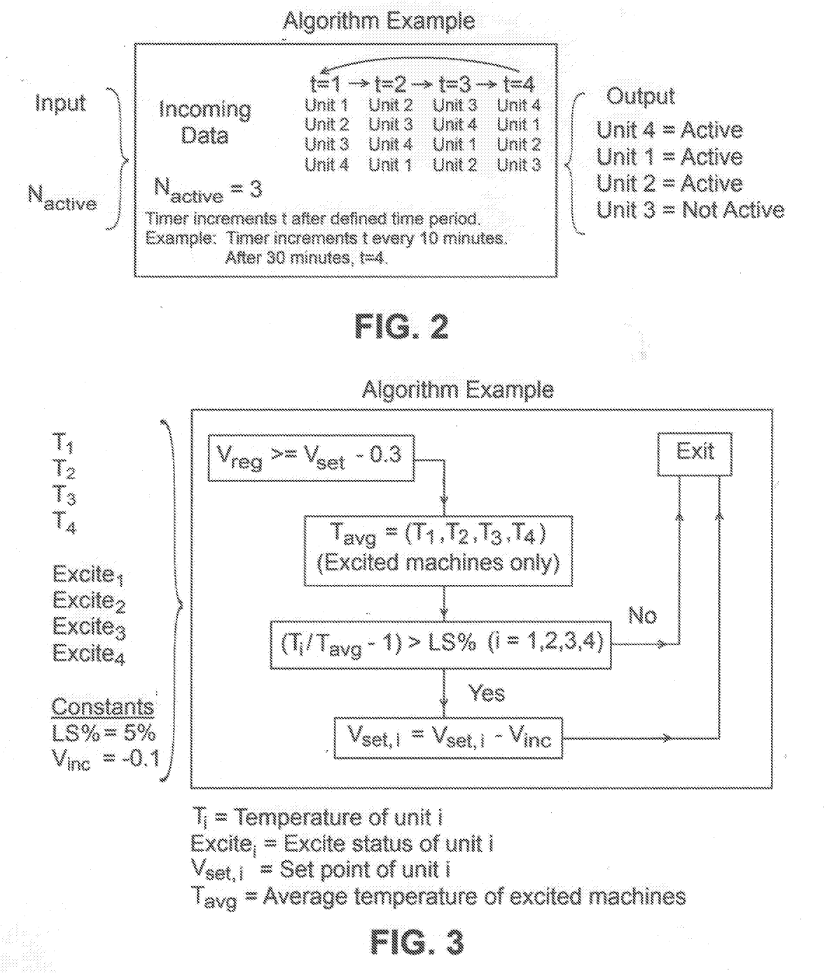

In a method embodiment, the system master controller 22 performs an active generator unit rotation scheduling algorithm which, with N_{active} (the number of active generator units 24 needed to accommodate the load 30) as its input, periodically rotates the numbered order of all generator units 24 in the system. Referring to FIG. 2, with the start of each new period t, which in the shown example is ten minutes, the listed generator units G1, G2, G3, G4 are rotated in order. In the exemplary embodiment, as each active generator rotation period is ten minutes and there is a total of four generator units 24 in the system 20, the rotating generator list returns to its initial form after four time periods have elapsed, i.e., after 40 minutes. As input N_{active} remains three, the first three listed generator units in each period are active, while the fourth is inactive. The shown output of this algorithm during the fourth period, during which t=4, indicates that G4, G1, and G2 are active, and G3 is not active. N_{active} changes as necessary to accommodate changes in the load 30, and so within any period t the number of active generator units can change, though the top-most listed generator unit 24 will continue as active in that period t. Notably, even if a generator unit 24 is considered as a master generator unit (in which its generator controller 26 and the system master controller 22 are integrated, as described above), that generator unit will be rotated into and out of active service like any other generator unit 24 of the system 20.

In a method embodiment, the system master controller 22 also performs a load share algorithm having as an input the list of generator units 24 identified as active and not active, i.e., the output of the above-discussed active generator unit rotation scheduling algorithm. In the load share algorithm example shown in FIG. 3, the output of the active generator unit rotation scheduling algorithm is that all four generator units 24 are active (indicated in FIG. 3 as Excite₁, Excite₂, Excite₃, and Excite₄). Other inputs to the load share algorithm are the respective operating temperatures T of the active generator units provided by their respective generator controllers 26. Additionally, the load share algorithm utilizes a load share threshold LS and a voltage increment V_{inc} as constants. Other parameters used include the voltage the system 20 is regulated to provide, V_{reg}, and the present voltage setpoint Vₛₑₜ of each respective active generator unit 24. The load share threshold LS is equal to five percent, and is specified as the limit within which the operating temperature of each individual active generator unit 24 must be relative to the average operating temperature of all active generator units. Voltage increment V_{inc} is the increment by which the voltage setpoint Vₛₑₜ of a generator unit 24 may be incrementally reduced over a load balancing period, and is set, for example, to −0.1 volts. It is to be understood that V_{inc} may be a higher or lower magnitude than 0.1 volts, and though V_{inc} is a decremental value (e.g., −0.1 volts) in the particular embodiment presently being discussed, in other embodiments wherein the voltage setpoint of a cooler-running active generator unit is increased to help reduce the electrical load of the hotter-running generator unit, an alternative discussed above, may be an incremental value (e.g., +0.1 volts). A filter is provided to provide sufficient time for the load balancing period, whereby the results of reducing the load on a particular generator may be realized before further adjustment. The load balancing period may, for example, be approximately ten to 15 minutes.

The load share algorithm is applied to each active generator, and starts by determining whether that active generator's initial voltage setpoint Vₛₑₜ, is at least 0.3 volts higher than V_{reg}. If so, the average temperature of all active generator units, T_{avg}, is calculated. Each generator's operating temperature Tᵢ is individually assessed relative to T_{avg}. If Tᵢ for any generator unit 24 is greater than T_{avg} by more than allowed by the load share threshold LS (here, by more than 5%), that generator unit's voltage setpoint V_{set,i} is reduced by the specified voltage increment, V_{inc}.

The load balancing process is applied once to each of the active generator units 24 during a load balancing period, and then the process is repeated until all active generator units operate at a temperature within the load share threshold LS.

The following is a list of preferred embodiments according to the present disclosure:
1. A parallel generator system having a service life and including:

a system bus adapted for connection to an electrical load;

a plurality of generator units electrically connectable in parallel to the system bus, each generator unit active when providing electrical power to the system bus, various ones of the generator units being selectively active or inactive during the system service life; and

a plurality of controllers;

wherein a portion of the electrical load of an active generator unit is incrementally transferred to another active generator unit by a controller on the basis of an indication that the loads of the active generator units are disallowably unbalanced, whereby load share balancing among the plurality of generator units occurs over the system service life.
2. The parallel generator system of embodiment 1, wherein selective activation or deactivation of one or more generator units is determined by a controller on the basis of the load-required number of active generator units.
3. The parallel generator system of embodiment 1, wherein the plurality of generator units is subjected by a controller to a schedule by which the activation order of generator units in the system is periodically rotated.
4. The parallel generator system of embodiment 1, wherein each generator unit has a respective generator controller, each generator controller defining a controller,

wherein the operating temperature of each generator unit is monitored and communicated by the respective generator controller to a controller, and

wherein a portion of the electrical load of a first active generator unit is incrementally transferred to at least one other active generator unit by a controller on the basis of the operating temperature of the first active generator unit being higher than a permissible predetermined level, whereby the electrical load on the first active generator unit is reduced.
5. The parallel generator system of embodiment 4, wherein the permissible predetermined level is relative to the average operating temperature of all active generator units.
6. The parallel generator system of embodiment 5, wherein the permissible predetermined level is defined by a constant load share threshold LS.
7. The parallel generator system of embodiment 4, wherein the load reduction on the first active generator unit is effected by incrementally reducing the voltage setpoint of the first active generator unit until the operating temperatures of all active generator units are no higher than the permissible predetermined level.
8. The parallel generator system of embodiment 4, wherein the load reduction on the first active generator unit is effected by incrementally increasing the voltage setpoint(s) of the at least one other active generator unit until the operating temperatures of all active generator units are no higher than the permissible predetermined level.
9. The parallel generator system of embodiment 4, wherein the load reduction on the first active generator unit is effected by a combination of incrementally reducing the voltage setpoint of the first active generator unit and incrementally increasing the voltage setpoint(s) of the at least one other active generator unit until the operating temperatures of all active generator units are no higher than the permissible predetermined level.
10. The parallel generator system of embodiment 4, wherein an optionally included master controller is defined by a controller, the master controller in communication with each generator controller.
11. The parallel generator system of embodiment 10, wherein the optionally included master controller is separate and located remotely from each of the plurality of generator units.
12. The parallel generator system of embodiment 1, wherein the active generator unit from which a portion of the electrical load is incrementally transferred exhibits a significantly higher operating temperature relative to the operating temperature of at least one other active generator unit, the relatively significantly higher operating temperature indicative of the disallowably unbalanced load share, whereby the operating temperatures of active generator units of the system are substantially maintained, over time, near the average operating temperature of all of the active generator units and the service lives of the plurality of generator units tends towards equalization.
13. A method for using selective load reduction for load share balancing in a parallel generator system, including:

selectively activating or deactivating one or more of a plurality of generator units during a portion of the system service life;

determining an indication that the loads of the active generator units are disallowably unbalanced; and

using at least one controller to incrementally transfer a portion of the electrical load of an active generator unit to another active generator unit on the basis of the determined indication, whereby load share balancing among the plurality of generator units occurs over the system service life.
14. The method of embodiment 13, wherein selective activation or deactivation of one or more generator units is determined by a controller on the basis of the load-required number of active generator units.
15. The method of embodiment 13, further including:

using a controller to subject the plurality of generator units to a schedule by which the activation order of generator units in the system is periodically rotated.
16. The method of embodiment 13, further including:

using a controller defining a generator controller to monitor and communicate to a controller the operating temperature of a respective generator unit, and

incrementally transferring a portion of the electrical load of a first active generator unit to at least one other active generator unit by a controller on the basis of the operating temperature of the first active generator unit being higher than a permissible predetermined level, whereby the electrical load on the first active generator unit is reduced.
17. The method of embodiment 16, wherein the permissible predetermined level is relative to the average operating temperature of all active generator units.
18. The method of embodiment 17, wherein the permissible predetermined level is defined by a constant load share threshold LS.
19. The method of embodiment 16, further including:

reducing the load on the first active generator unit by at least one of incrementally reducing the voltage setpoint of the first active generator unit and incrementally increasing the voltage setpoint(s) of the at least one other active generator unit, until the operating temperatures of all active generator units are no higher than the permissible predetermined level.
20. The method of embodiment 16, wherein an optionally included master controller is defined by a controller in communication with each generator controller, the optionally included master controller separate and located remotely from each of the plurality of generator units.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A parallel generator system having a service life and including:
a system bus adapted for connection to an electrical load;
a plurality of generator units electrically connectable in parallel to the system bus, each generator unit active when providing electrical power to the system bus, various ones of the generator units being selectively active or inactive during the system service life; and
a plurality of controllers;
wherein a portion of the electrical load of an active generator unit is incrementally transferred to another active generator unit by a controller on the basis of an indication that the loads of the active generator units are disallowably unbalanced, whereby load share balancing among the plurality of generator units occurs over the system service life.

2. The parallel generator system of claim 1, wherein selective activation or deactivation of one or more generator units is determined by a controller on the basis of the load-required number of active generator units.

3. The parallel generator system of claim 1, wherein the plurality of generator units is subjected by a controller to a schedule by which the activation order of generator units in the system is periodically rotated.

4. The parallel generator system of claim 1, wherein each generator unit has a respective generator controller, each generator controller defining a controller,
wherein the operating temperature of each generator unit is monitored and communicated by the respective generator controller to a controller, and
wherein a portion of the electrical load of a first active generator unit is incrementally transferred to at least one other active generator unit by a controller on the basis of the operating temperature of the first active generator unit being higher than a permissible predetermined level, whereby the electrical load on the first active generator unit is reduced.

5. The parallel generator system of claim 4, wherein the permissible predetermined level is relative to the average operating temperature of all active generator units.

6. The parallel generator system of claim 5, wherein the permissible predetermined level is defined by a constant load share threshold LS.

7. The parallel generator system of claim 4, wherein the load reduction on the first active generator unit is effected by incrementally reducing the voltage setpoint of the first active generator unit until the operating temperatures of all active generator units are no higher than the permissible predetermined level.

8. The parallel generator system of claim 4, wherein the load reduction on the first active generator unit is effected by incrementally increasing the voltage setpoint(s) of the at least one other active generator unit until the operating temperatures of all active generator units are no higher than the permissible predetermined level.

9. The parallel generator system of claim 4, wherein the load reduction on the first active generator unit is effected by a combination of incrementally reducing the voltage setpoint of the first active generator unit and incrementally increasing the voltage setpoint(s) of the at least one other active generator unit until the operating temperatures of all active generator units are no higher than the permissible predetermined level.

10. The parallel generator system of claim 4, wherein an optionally included master controller is defined by a controller in communication with each generator controller.

11. The parallel generator system of claim 10, wherein the optionally included master controller is separate and located remotely from each of the plurality of generator units.

12. The parallel generator system of claim 1, wherein the active generator unit from which a portion of the electrical load is incrementally transferred exhibits a significantly higher operating temperature relative to the operating temperature of at least one other active generator unit, the relatively significantly higher operating temperature indicative of the disallowably unbalanced load share, whereby the operating temperatures of active generator units of the system are substantially maintained, over time, near the average operating temperature of all of the active generator units and the service lives of the plurality of generator units tends towards equalization.

13. A method for using selective load reduction for load share balancing in a parallel generator system, including:
selectively activating or deactivating one or more of a plurality of generator units during a portion of the system service life;
determining an indication that the loads of the active generator units are disallowably unbalanced; and
using at least one controller to incrementally transfer a portion of the electrical load of an active generator unit to another active generator unit on the basis of the determined indication, whereby load share balancing among the plurality of generator units occurs over the system service life.

14. The method of claim 13, wherein selective activation or deactivation of one or more generator units is determined by a controller on the basis of the load-required number of active generator units.

15. The method of claim 13, further comprising:
using a controller to subject the plurality of generator units to a schedule by which the activation order of generator units in the system is periodically rotated.

16. The method of claim 13, further comprising:
using a controller defining a generator controller to monitor and communicate to a controller the operating temperature of a respective generator unit, and
incrementally transferring a portion of the electrical load of a first active generator unit to at least one other active generator unit by a controller on the basis of the operating temperature of the first active generator unit being higher than a permissible predetermined level, whereby the electrical load on the first active generator unit is reduced.

17. The method of claim 16, wherein the permissible predetermined level is relative to the average operating temperature of all active generator units.

18. The method of claim 17, wherein the permissible predetermined level is defined by a constant load share threshold LS.

19. The method of claim 16, further comprising:
reducing the load on the first active generator unit by at least one of incrementally reducing the voltage setpoint of the first active generator unit and incrementally increasing the voltage setpoint(s) of the at least one other active generator unit, until the operating temperatures of all active generator units are no higher than the permissible predetermined level.

20. The method of claim 16, wherein a controller defines an optionally included master controller in communication with each generator controller, the optionally included master controller separate and located remotely from each of the plurality of generator units.
